(19) United States
(12) Patent Application Publication
(10) Pub. No.: US 2005/0217718 A1
(43) Pub. Date: Oct. 6, 2005

(54) Method and tabbing station for fitting tabs to a solar cell, and method and apparatus for manufacturing a solar panel

(75) Inventors: Franciscus C. Dings, Veldhoven (NL); Paul A.M. Lindelauf, Veldhoven (NL); Robbert H. Backer, Waalre (NL); Marinus F.J. Evers, Heeze (NL)

Correspondence Address: PILLSBURY WINTHROP SHAW PITTMAN, LLP, P.O. BOX 10500, MCLEAN, VA, 22102, US

(73) Assignee: OTB GROUP B.V., EINDHOVEN (NL)

(21) Appl. No.: 10/515,063

(22) PCT Filed: May 20, 2003
(86) PCT No.: PCT/NL03/00372

§ 371 Date: Apr. 28, 2005

(30) Foreign Application Priority Data
May 21, 2002 (NL) 1020627

(51) Int. Cl. H01L 31/00

(52) U.S. Cl. 136/256

(57) ABSTRACT

A method for connecting a conductive metal strip, or tab, to a solar cell, which solar cell is provided with metal attachment points, in which a tab is placed at a respective attachment point, wherein the connection between the respective attachment point and the tab is realized by a non-contact connecting technique. The invention also relates to an apparatus for manufacturing solar panels, preferably using the method, wherein the apparatus is provided with: a tabbing station in which solar cells are provided with tabs; a stringing station in which the solar cells provided with tabs in the tabbing station are placed next to each other on a translucent plate and where suitably chosen tabs of the solar cells are interconnected; and a laminating station in which the plate with solar cells coming from the stringing station is provided with at least one layer for covering the solar cells.

The invention relates to a method for connecting a conductive metal strip or tab, to a solar cell, which solar cell is provided with metallized attachment points, wherein a tab is placed at a respective attachment point, wherein the connection between the respective attachment point and the tab is realized by means of a non-contact connecting technique.

EP-A-1 205 982 discloses such method wherein the non-contacting connecting technique is effected by directing a hot gas to the spot where the connection has to be established. The time needed for formation of the connection in EP-A-1 205 982 is approximately 3-10 seconds. GB1 385 112 discloses a method wherein the non-contact connecting technique is pulsed laser welding process.

The invention also relates to a method and an apparatus for manufacturing a solar panel.

Solar cells need to be interconnected to form a solar panel. To connect solar cells, use is made of so-called tabs. A tab is a strip of metal, which is connected to an attachment point present on the solar cell.

To date, in the manufacture of solar cells, this connection is generally established using a soldering iron, which is hand-operated.

A drawback of hand-fitting tabs on solar cells, using a soldering iron, is that the solar cell is locally thermally stressed for some time, this time not being exactly defined, which can cause damage to the solar cell. In addition, when removing the soldering iron, the tabs may be pulled loose from the attachment point, so that no proper connection is established between the attachment point and the tab.

The above mentioned British patent provides a solution to these problems. According to the invention another solution is provided by a method for connecting a conductive metal shop, or tab, to a solar cell which solar cell is provided with metallized attachment points, wherein a tab is placed at a respective attachment point, wherein the connection between the respective attachment point and the tab is realized by means of a non-contact connecting technique, wherein the method according to the invention is characterized in that the non-contact connecting technique comprises directing a frame at the tab at the location of the attachment point for a short time, wherein the short time is in the range of 0.1-1.5 s, more in particular in the range of 0.2-0.5 s. The invention also provides a tabbing station for connecting a conductive metal strip, or tab, to a solar cell, which solar cell is provided with metallized attachment points, wherein a tab is placed at a respective attachment point, wherein the tabbing station is provided with a non-contact connecting technique device by means of which a connection between a tab and an attachment point can be realized, wherein the tabbing station is characterized in that the non-contact connecting technique comprises directing a fine at the tab at the location of the attachment point for a short time, wherein the short time is in the range of 0.1-1.5 s, more in particular in the range of 0.2-0.5 s. Further, the invention provides a stringing station for interconnecting a number of solar cells provided with tabs, which stringing station is provided with a non-contact connecting technique device by means of which a connection between suitably chosen tabs of adjacent solar cells can be established, wherein the non-contact connecting technique device comprises a flame soldering device which is arranged to direct a small flame formed by the flame soldering device at contact points between tabs of adjacent solar cells for a short time, wherein the short time is in the range of 0.1-1.5 s, more in particular in the range of 0.2-0.5 s.

Because the connection between the respective attachment point of the solar cell and the tab is realized using a non-contact connecting technique in the form of flame soldering, the formation of a connection is effected in a non-contact manner. This means that the tabs will not be pulled loose after forming the attachment. In addition, the flame soldering technique is particularly fast since the techniques need to be applied to the tab for only a few tenths of seconds per attachment point. The thermal stress on the solar cell is thus reduced to a minimum. In addition, the flame soldering device can be simply mounted on a manipulator known per se, such as, for instance, a robot. Then, only measures have to be taken to automatically position a tab on a solar cell in order to achieve a completely automated process for fitting tabs on a solar cell.

Since a solar cell needs to be provided with, for instance, six tabs, with each tab needing to be connected to the soar cell at three attachment points, hand-fitting tabs on solar cells is particularly labor-intensive and expensive. The interconnection of each solar cells for forming a solar panel is also done by hand and is particularly labor-intensive. In particular when solar panels of different dimensions need to be manufactured, a flexible system for manufacturing such solar panels is desired. For this purpose, the invention provides a method for manufacturing a solar panel, wherein in a tabbing station, solar cells are provided with tabs, wherein in a stringing station, the solar cells provided with tabs in the tabbing station are placed next to each other on a translucent plate and wherein before or after placing, suitably chosen tabs of the solar cells are interconnected, wherein the translucent plate, having thereon the solar cells interconnected in the stringing station is transported by a conveyor to a laminating station, wherein in the laminating station the plate is then provided with at least one layer for covering the solar cells.

The invention also provides an apparatus for manufacturing solar panels, wherein the apparatus is provided with:
a tabbing station in which solar cells are provided with tabs;
a stringing station in which the solar cells provided with tabs in the tabbing station are placed next to each other on a translucent plate and wherein subsequently or beforehand, suitably chosen tabs of the solar cells are interconnected;
a laminating station in which the plate having thereon the solar cells interconnected in the stringing station is provided with at least one layer for covering the solar cells, wherein at least the stringing station and the laminating station are provided with a conveying device by means of which a translucent plate can be conveyed through the said stations.

The constructions of the stations which each have their own specific function, offers the possibility to supply a varied feed to each station. For instance, into the tabbing station, different types of solar cells can be fed. The translucent plates fed into the stringing station can also have different dimensions and/or properties. In this manner, solar panels of different dimensions, provided with solar cells of different types, can be manufactured in one single apparatus. This yields the required flexibility, so that small aeries of solar panels can also be manufactured in an automated manner. An example of this would be a tabbing station in which approximately 2,000 solar cells per hour can be provided with tabs. In this manner, approximately 27 panels per hour can be manufactured, which results in a production of approximately 50,000 panels a year. It is noted that the advantages of greater flexibility can also be achieved by means of other connecting techniques than non-contact connecting techniques; for instance, the tabbing station can be designed with a traditional soldering iron or with a device for ultrasonic welding. It will be clear, however, that the particular advantages of fast non-contact connecting techniques, each as flame soldering and the like, are especially brought out in an automated process. This is because, in an automated process, the connecting process should preferably go perfectly, so that failures during the automated providing of the connection are reduced to a minimum.

According to a further elaboration of the apparatus according to the invention, the apparatus can further be provided with a pre-assembly station in which the dimensions of the translucent plate are determined and made known to the control so that in the stringing station, the correct number of solar cells can be placed on the translucent plate and the required connections can be provided.

It should be noted that “Advanced automation techniques for interconnecting thin silicon solar cells”, published on May 12, 1994 describes an automated assembly of strings of solar cells. The publication does not relate to a flexible integrated method and an apparatus for manufacturing complete solar panels with different dimensions, wherein the dimensions of the cells can vary as well.

Further elaborations of the invention are described in the subclaims and will be further explained hereinafter with reference to the drawing, in which

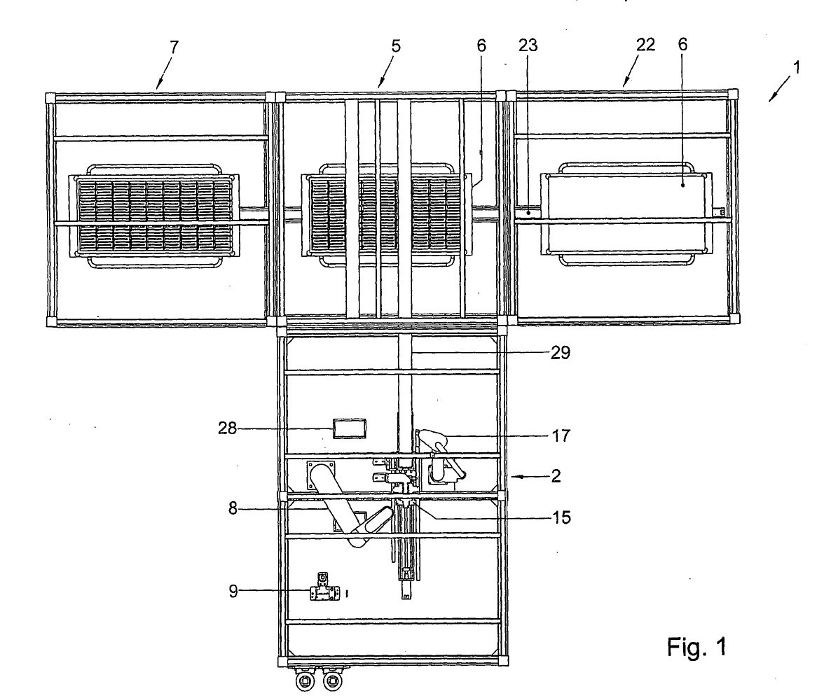

FIG. 1 shows a top plan view of an apparatus according to the invention;

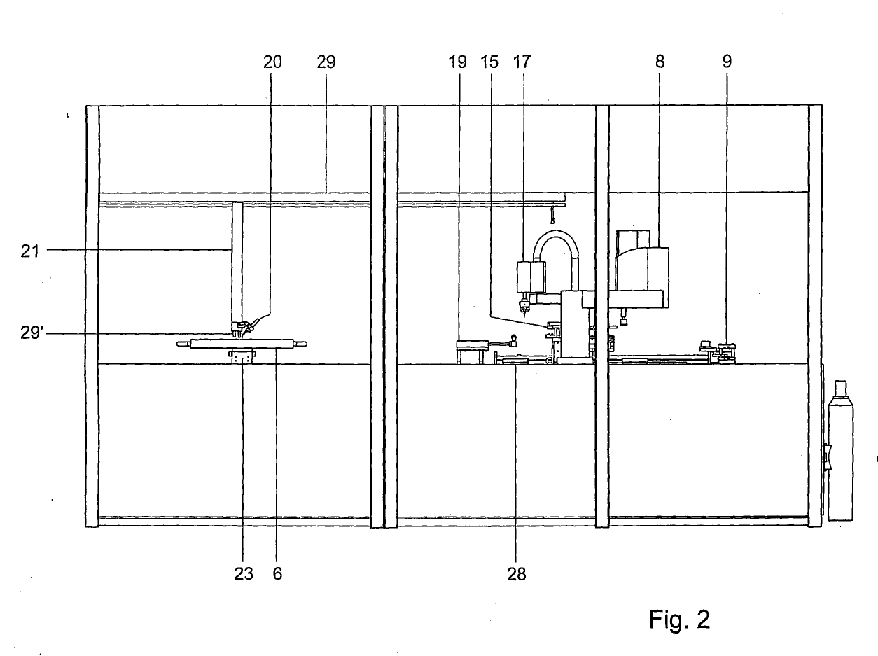

FIG. 2 shows a left side view of the apparatus shown in FIG. 1;

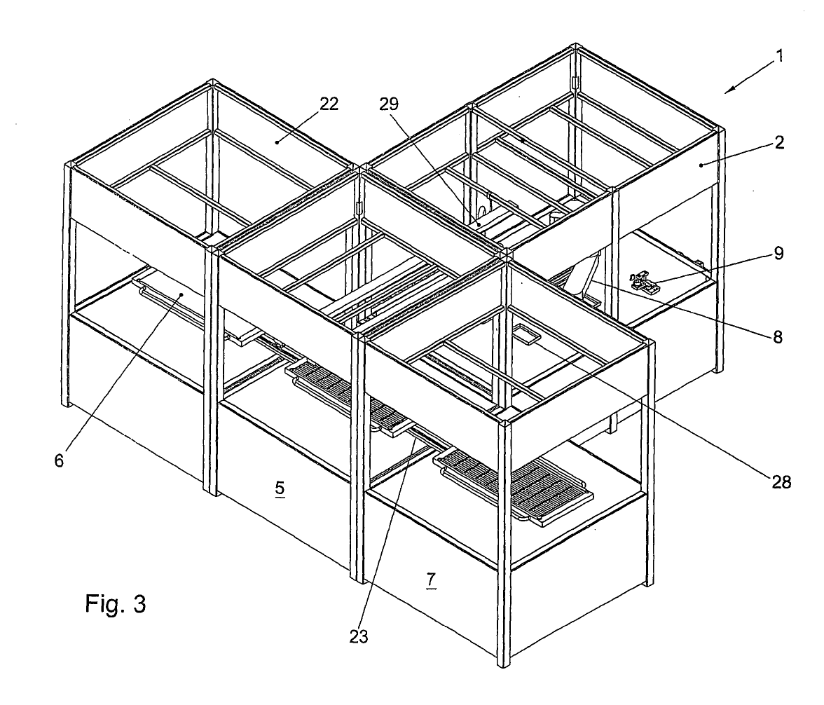

FIG. 3 shows a perspective view of the apparatus shown in FIGS. 1 and 2;

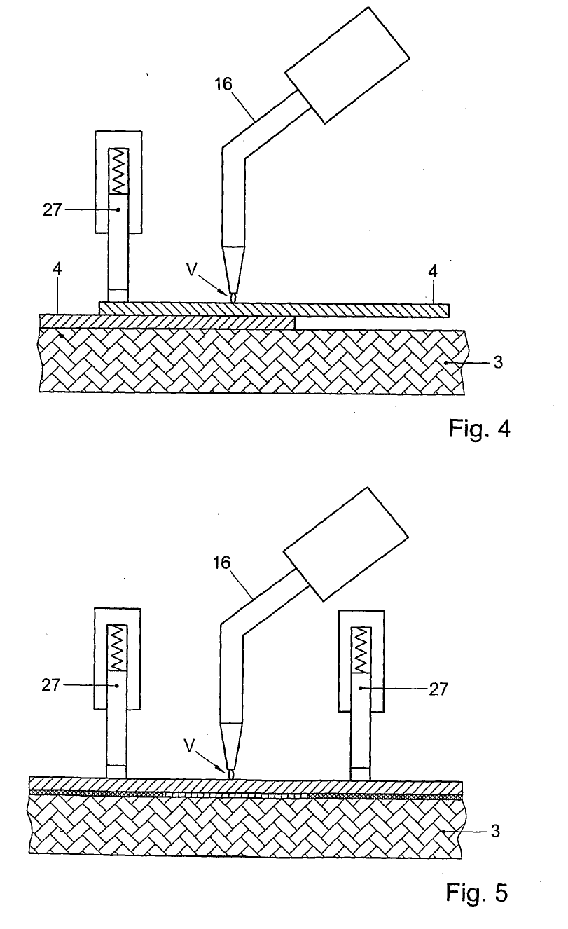

FIG. 4 shows the connecting of two tabs using a flame soldering apparatus;

FIG. 5 shows the connecting of a tab at an attachment point of a solar cell using a flame soldering apparatus;

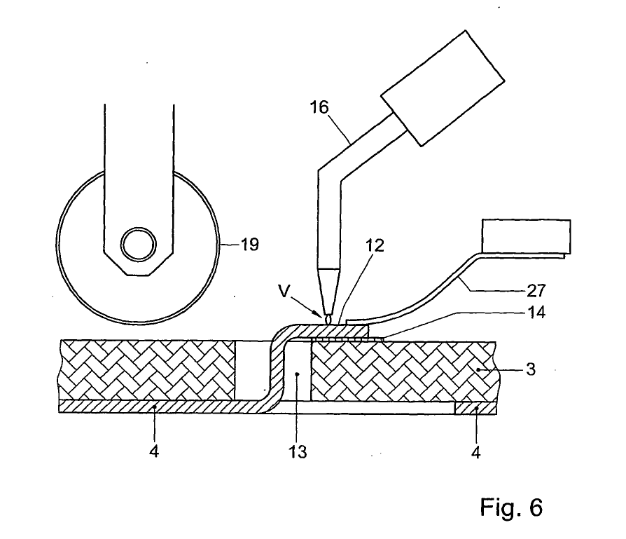

FIG. 6 shows the connecting of a lip of a tab at an attachment point of the solar cell on the sun side using a flame soldering apparatus;

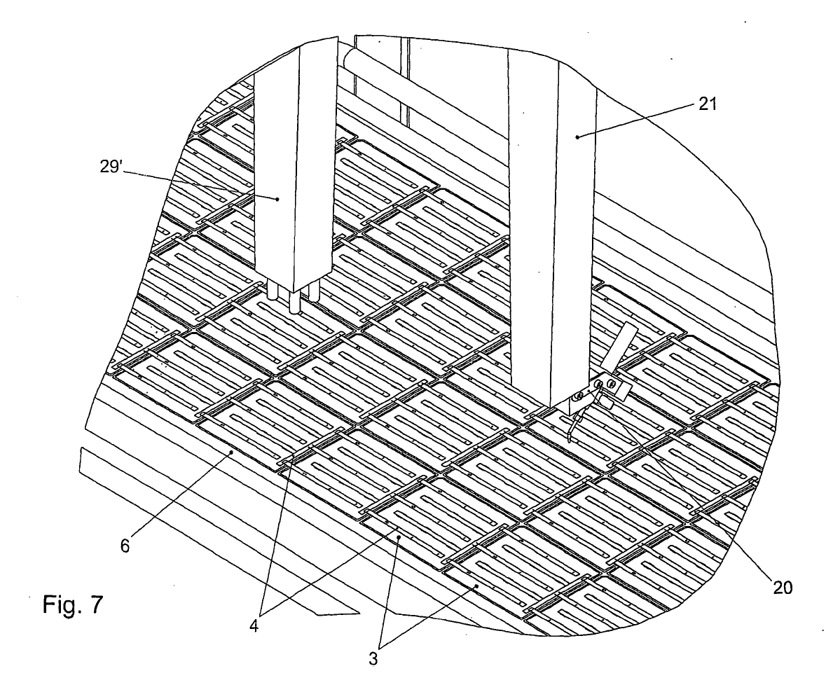

FIG. 7 is a perspective view of a part of the stringing station;

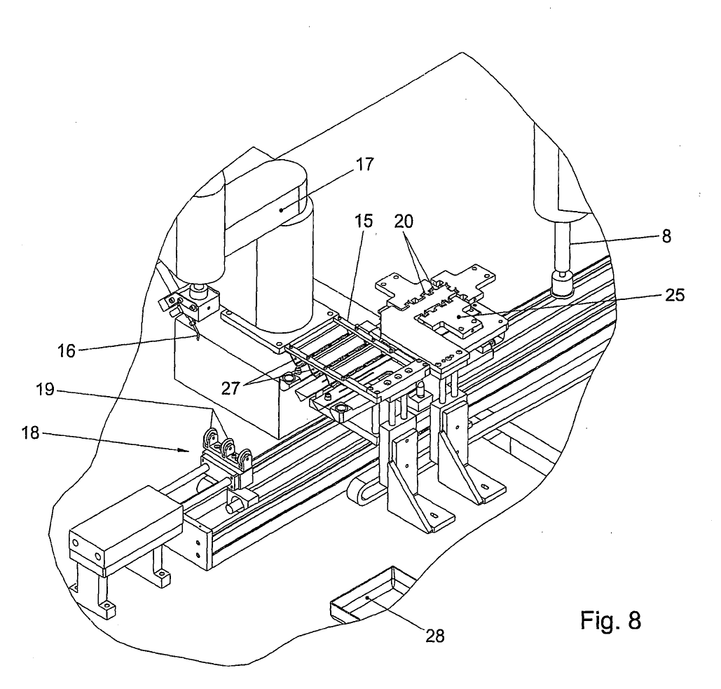

FIG. 8 is a perspective view of a part of the tabbing station;

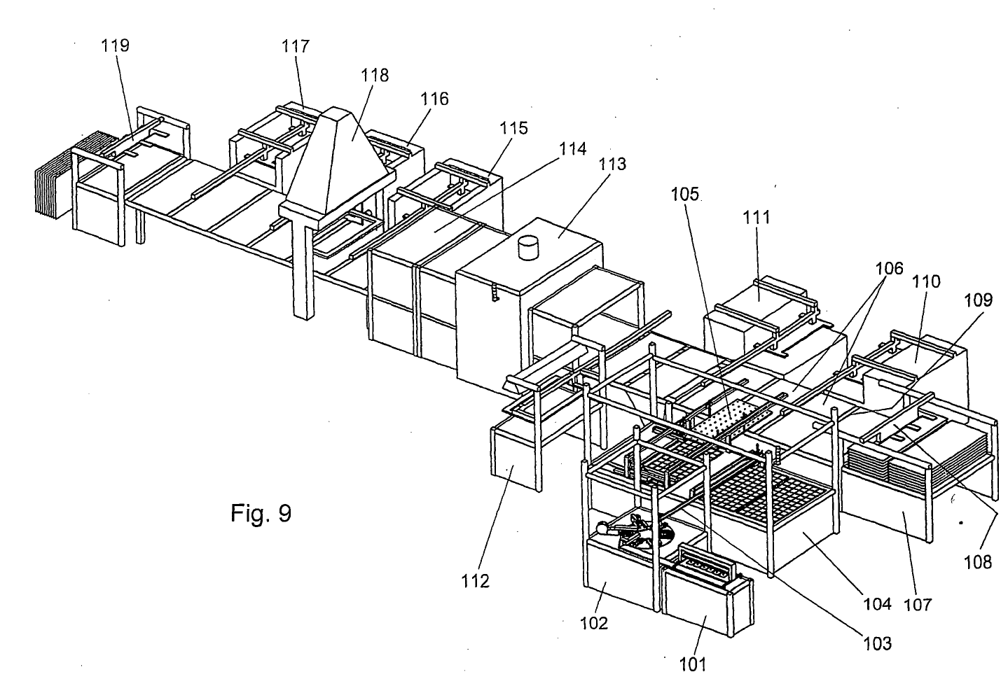

FIG. 9 is a perspective view of a second exemplary embodiment of an apparatus according to the invention;

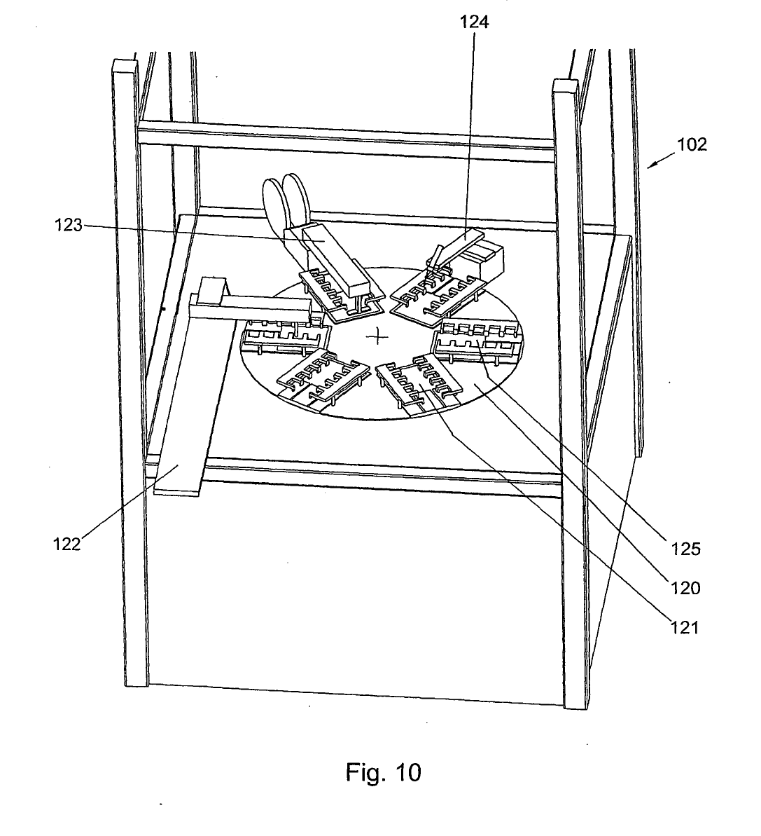

FIG. 10 is a perspective view of the tabbing station of the second exemplary embodiment of FIG. 9;

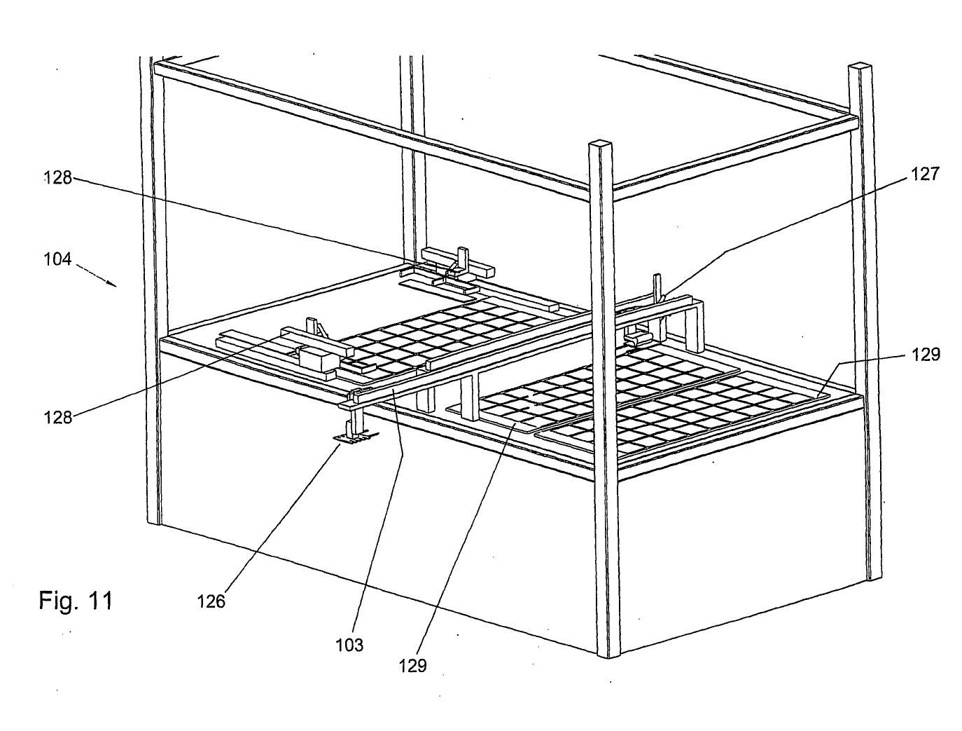

FIG. 11 is a perspective view of the stringing station of the second exemplary embodiment of FIG. 9.

The apparatus 1 shown in top plan view in FIG. 1 is intended for manufacturing solar panels in a flexible manner. For this purpose, the apparatus is provided with a tabbing station 2 in which solar cells 8 are provided with tabs 4 (see FIGS. 4-7). The apparatus is further provided with a stringing station 5 in which the solar cells 3 provided with tabs 4 in the tabbing station are placed next to each other on a translucent plate 6 and where suitably chosen tabs 4 of solar cells 3 are interconnected. In a laminating station 7, the translucent plate 6 having therein the solar cells 3 interconnected in the stringing station 5 is provided with at least one layer for covering the solar cells. Into a pre-assembly station 22, the plates 6 are fed, on which later, in the stringing station 5, the solar cells 3 provided with tabs 4 will be placed. In a pre assembly station 22, the dimensions of a plate 6 can, for instance, be determined and a release coating can be applied on this plate. In the pre-assembly station 22, on such a glass plat, a coating can be applied such as, or instance, an EVA coating which is slightly elastic, so that irregularities on the sun side of the solar cells 8 can be compensated for by this elastic coating.

The tabbing station 2 is provided with a conveyor 8 for conveying solar cell substrates 3. It the present exemplary embodiment, the conveyor comprises a manipulator 8.

The tabbing station 2 in the present exemplary embodiment is further provided with a tab manufacturing unit 9 by means of which tabs 4 of a desired length can be manufactured from a roll of strip material. In a punching device provided in the tabbing station 2, which can be part of the tab manufacturing unit, lips 12 (see FIG. 6) can be formed on the tabs. Such lips 12 serve, as shown in FIG. 6, to be able to bring a part of the tab 4 through an opening 13 in the solar cells 8 to the sun side of the solar cell 3 in order to be connected there to an attachment point 14 provided on the solar cell 3. Such an attachment point can, for instance, be a soldering material locally applied using a printing technique. It is noted that some solar cells 3 do not possess openings 13 and attachment points 14 on the sun side of the solar cells 8. In that case, the tabs 4 are connected to an attachment point 14 on the side of the solar cells 3 which is, in use, remote from the sun. Such an embodiment is shown in FIG. 5.

FIG. 4, finally, shows the interconnecting of two tabs 4, which can, for instance, be done in the stringing station 5.

As shown in more detail in FIG. 8, the tabbing station is provided with a positioning unit 15 by means of which a number of tabs 4 can be positioned on a solar cell substrate 9. Also, a flame soldering device 16 is clearly visible by means of which a connection between a tab 4 and an attachment point 14 can be realized by directing a small flame V at the tab 4 at the location of the attachment point 14 for a short time. According to an alternative elaboration of the invention, the tabbing station, instead of being provided with the fine soldering device 16, could be provided with a soldering iron by means of which a connection between a tab 4 and an attachment pt 14 can be realized by pressing the soldering iron on the tab 4 at the location of the attachment point 4 for a short time. Other non-contact connecting techniques, such as laser welding, laser soldering and infrared soldering or connecting techniques involving contact, such as ultrasonic welding, are also possible. Further, FIG. 8 clearly shows that the flame soldering devise 16 is mounted on a manipulator 17, so that the flame soldering device 16 can be quickly placed above the various attachment points 14 of a solar cell substrate 3. Because a particularly short time is required to establish a connection between a tab 4 and an attachment point 14, the solar call 3 can be particular fast provided with the required tabs 4. FIG. 8 also shows a bending device 18 for bending the lips 12 at the attachment points 14 of the solar cell substrate 3. In the present exemplary embodiment, this bending device comprises three wheels 19 which, after the lips 12 are pressed through the openings 18 in the solar cells 8 by means of pins 20, are driven over the sun side of the solar cell 3, causing the lips 12 to be pressed against the sun side of the solar cell 3. A wheel 19 is also shown in FIG. 4.

FIG. 8 further shows a part of a wetting unit 28 by means of which a tab 4 located in the positioning unit can be wetted with a liquid which promotes the establishment of the connection between the tab 4 and the attachment point 14, more in particular a flux. Such a wetting unit 28 can, for instance, comprise a profiled sponge, which is included in a reservoir with the respective liquid. A tab 4 to be wetted with the active liquid is briefly pressed on the profiled sponge by a handling device, so that the tab 4 is brought into contact with the tops of this profiled sponge. In this manner, it is elected that the tab 4 is only locally wetted. Of course, the tops of the sponge have to be positioned such that the wetting of the tab 4 takes place at those points of the tab 4 which will later be in contact with the attachment points 14 of the solar cell 3.

In the tabbing station, a second conveyor 29 is located, which, in the present case, is designed as a gantry conveyor 29. This conveyor 29 also extends ado the stringing station 5, so that by means of that conveyor 29, solar cell substrates from the tabbing station 2 we are provided with tabs 4 can be placed on a translucent plate 6 located in the stringing station 5.

The string station 5 is also provided with a flame soldered device 20. Optionally, a soldering iron, an ultrasonic welding device, an infrared soldering device, a laser welding or laser soldering device can be provided instead. The flame sided device 20 is mounted on a manipulator 21, so that the flame soldering device 20 can be quickly placed above the various attachment points 14 of the different solar cell substrates 3 for interconnecting the different solar cell substrates 3.

The pre-assembly station 22, the winging station 5 and the laminating station 7 are provided with a conveying device 28 by means of which a translucent plate 6 can be convoyed through these stations.

In the laminating station 7, means will further be present for providing a sealing layer for the protection of the interconnected solar cells placed on the glass plate.

In the laminating station 7, means can be present for creating connecting points for electrical connection of the solar panel.

Solar cell substrates from, for instance, a buffer or inspection station are fed into the tabbing station 2. Than, a tab 4 is manufactured from strip material using the tab manufacturing unit 9 and lips 12 are formed on the tabs 4 using the punching machine. In order to promote the flame soldering process, the tab 4 is brought into contact with the profiled sponge at desired positions, so that the tab 4 is wetted at the desired positions with liquid in which the sponge has been soaked. The tab 4 is then positioned on a solar cell 3 which is ready on a tilting table of the positioning unit 15, with the back of the solar cell 3 fact upwards. Then, a pin lid 25, which is hingedly connected to the tilting table 24, is let down on the solar cell so that the pins 20 press the lips 12 through the openings 13 in the solar cell 3. Then, the wheels 19 move over the sun side of the solar cells, bending the lips 12. Retainers 27 are then used to keep the lips 12 in this position, after which, by means of the flame soldering device 16, successively, the various lips 12 are rapidly heated for a short time, so that the lips 12 are connected to the attachment points 14.

After the various tabs 4 have been connected to the solar cell 8, the solar cell 3 is moved from the tabbing station 2 to the stringing station 5 using the conveying device 29. Optionally, the solar cell 3 is first placed in an interface in the stringing station 5. It is, however, also possible for the solar cell 3 to be positioned directly on a translucent plate 6 located in the stringing station 5. When a number of adjacent solar cells 3 are placed on the translucent plate 6, subsequently the various interconnections between the solar cells 3 can be established using a flame soldering device 20.

The translucent plate 6 comes from the pre-assembly station 22 in which the dimensions of the place have been determined and in which this plate 6 has optionally been provided with an EVA layer which, inter alia, serves to compensate for irregularities on the sun side of the solar cells 3. After all solar cells are interconnected in the stringing station 5, the translucent plate 6 with the solar cells 3 is conveyed to the ting station 7 in which a protective layer is applied on the solar cells and in which the connecting points for the electrical connection of the solar panel are manufactured.

Such an apparatus can be used to manufacture solar panels of different dimensions, while the solar cells 3 present in these solar panels can also possess different dimensions and properties. The station-wise construction of the apparatus, with interfaces being optionally arranged in the stations, in which the semi-manufactured products manufactured in an upstream station can be delivered and, optionally, can be temporarily stored, yields this high degree of flexibility. For instance, the solar cells can have a square shape with an edge length of 125 mm or 150 mm. The solar panels can, for instance, contain 10 to 100 solar cells. The solar cells themselves can have different efficiencies. In the interfaces, the solar cells can be stored in a position of which the coordinates are known exactly, so that a conveying device of a station can pick up a solar cell of any size therefrom. The flame soldering technique is ft a moreover, non-contact, so the chances of damage to the tab and the solar cell are reduced to a minimum.

The second exemplary embodiment shown it FIGS. 9-11 shows a destacking station 101 by means of which individual solar cells can be moved to a tabbing station 102. In the tabbing station 102, the individual solar cells are provided with tabs. Then, a solar cell 126 provided with tabs is conveyed to a stringing station 104 using a conveyor 103. In the present exemplary embodiment, the solar cells 126 are first placed on a mounting plate 129 and then interconnected using a flame soldering device 127, 128. Then, a thus interconnected set of solar cells 126 is picked up by a pick up plate 105 provided with auction cups and placed on a glass plate 106. These glass plates 106 come from a buffer station 107 provided with a destacker 108. By means of the film supplying station 110 set up next to a conveyor belt 109 an EVA film is placed on the glass plate 108. Optionally, a second film supplying station 111 can be used to apply a film over the solar cells placed on the glass plate. Further, with a repair station 112, optionally, a repair to the panel can be carried out before the panel disappears into a laminating station 118. After the laminating station 113, the cooling of the laminated panels takes place in cooling stations 114. By means of stations 115, 116 and 117, for instance, the edges of the panel can be cut to shape, tests can be done and connection points can be mounted on the panel. Station 118 can be used to do a so-called flash test. Finally, a discharge station 119 is used to discharge the thus manufactured panels from the line.

FIG. 10 sows the tabbing station 102 in more detail. The tabbing station 102 is provided with a turret 120 provided with six holders 121 for individual solar cells 126. By means of a feed unit 122, each time a solar cell is placed on a holder 121 of the turret 120. Next to the turret 120, a tab supply unit 123 is placed by means of which tabs can be cut onto length from a strip of tab material wound on a feed roll and can be positioned on the solar cell. Then the turret rotates 60 degrees, so that the respective solar cell arrives at a flame soldering unit 124 where the tab is connected to the solar cell. In a discharge position 125, the tabbed solar cell is discharged to the stringing station 104

FIG. 11 shows the stringing station 104 which using the conveyor 103, is fed with tabbed solar cells 126. These solar cells 126 are placed on a mounting plate 129, after which the adjacent tabbed solar cells 126 are then interconnected using a flame soldering device 127. Options, further connections can be established using further flame soldering devices 128. It will bs clear that the stringing station 104 is provided with conveying means for conveying the mounting plates 129 therein. The exemplary embodiment clearly shows that the solar cells of a panel can already have been interconnected before these solar cells are placed on a glass plate 106. In addition, it will be close that the second exemplary embodiment also yields a high degree of flexibility with regard to the dimensions of the panels and the dimensions of the solar cells.

It will be clear that the intention is not limited to the exemplary embodiment descried, but that various modifications are possible within the scope of the invention as defined by the claims.

1. A method for connecting a conductive metal strip, or tab, to a solar cell, said solar cell being provided with metallized attachment points, the method comprising:
placing a tab at a respective attachment point, and
connecting the respective attachment point and the tab using a non-contact connecting technique,
wherein said connecting comprises directing a flame at the tab at a location of the attachment point for a short time in the range of about 0.1-1.5 s.

2. A method according to claim 1, further comprising before placing the tab at the attachment point, locally wetting the tab with a flux.

3. A method according to claim 1, further comprising, before placing the tab on the solar cell, unwinding a strip of tab material from a roll and cutting said strip of tab material to a desired length to form the tab.

4. A method according to claim 1, wherein the attachment point is located on a back of the solar cell which is, in use, remote from the sun, and wherein, after attachment to the attachment point, the tab extends on said back.

5. A method according to claim 1, wherein the attachment point is located on a front side of the solar cell which, in use, faces the sun, and wherein, near said attachment point, an opening is provided in the solar cell, wherein the method further comprises, prior to connecting the tab to a respective attachment point, forming a lip on the tab, and bringing the lip through a corresponding opening.

6. A method according to claim 5, wherein the lip is formed by a punching operation.

7. A method for manufacturing a solar cell, comprising:
providing the solar cell with a plurality of tabs extending parallel to each other, said providing including
placing each of the plurality of tabs at a respective attachment point on the solar cell, and
connecting the respective attachment point and the tab using a non-contact connecting technique, and
interconnecting a first plurality of said plurality of tabs with a cross tab using a said non-contact connecting technique.

8. A method according to claim 7, wherein a second plurality of the plurality of tabs, extending parallel to each other each, extend by an end beyond a side edge of the solar cell, said end being connectable to a cross tab of an adjacent solar cell to form a series of solar cells connected in series.

9. A method for manufacturing a solar panel, comprising:
providing a plurality of solar cells with tabs, said providing including, for each of the plurality of solar cells
placing a tab at a respective attachment point on a solar cell, and
connecting the respective attachment point and the tab using a non-contact connecting technique,
placing the plurality of solar cells, next to each other on a translucent carrier plate, and
subsequently or prior to placing the plurality of solar cells next to each other on a translucent carrier plate, interconnecting suitably chosen tabs of adjacent solar cells using said non-contact connecting technique to contact points between tabs of adjacent solar cells.

10. A method according to claim 9, wherein suitably chosen tabs of adjacent solar cells are interconnected with a connecting tab, wherein the connecting tab is connected to the tabs of the adjacent solar cells by applying said non-contact connecting technique to contact points between a respective connecting tab and a solar cell tab.

11. A method according to claim 9, further comprising, after interconnecting the solar cells, applying a sealing layer on the solar cells.

12. A method for manufacturing a solar panel, comprising:
providing solar cells with tabs in a tabbing station;
placing the solar cells provided with tabs in the tabbing station next to each other on a translucent plate in a stringing station;
before or after placing the solar cells, interconnecting suitably chosen tabs of the solar cells;
transporting the translucent plate, having thereon the solar cells interconnected in the stringing station, with a conveyor to a laminating station, and
covering the solar cells with a layer of material in the laminating station.

13. A method according to claim 12, further comprising feeding the translucent plate into a pre-assembly and identifying the translucent plate in the pre-assembly to obtain, the dimensions of the plate, so that the number of solar cells to be placed on the plate can be determined.

14. A method according to claim 12, further comprising supplying solar cell substrates provided with metallized attachment points into the tabbing station and connecting tabs to the solar cell substrates at said attachment points.

15. A method according to claim 14, wherein the tabs are manufactured in the tabbing station by cutting off a metal strip to a desired length and pressing said tabs on the solar cell substrates at a location of said attachment points.

16. A method according to claim 14, wherein a connection between the respective attachment point and the tab is realized by a non-contact connecting technique.

17. A method according to claim 14, wherein a connection between the respective attachment point and the tab is realized using soldering iron, ultrasonic welding or similar contact connecting techniques.

18. A method according to claim 12, wherein, in the stringing station, the tabs of adjacent solar cells are interconnected by applying a non-contact connecting technique to contact points between tabs of adjacent solar cells.

19. A method according to claim 12, wherein, in the stringing station, the tabs of adjacent solar cells are interconnected by applying a contact connecting technique to contact points between tabs of adjacent solar cells.

20. A method according to claim 12, wherein in the laminating station, a sealing layer is applied on the solar cells and wherein connecting points for electrical connection of the solar panel are created.

21. An apparatus for manufacturing solar panels, comprising
a tabbing station in which solar cells are provided with tabs;
a stringing station in which the solar cells provided with tabs in the tabbing station are placed next to each other on a translucent plate and wherein subsequently or prior to placing the solar cells next to each other on a translucent plate, suitably chosen tabs of the solar cells are interconnected, and
a laminating station in which the plate, having thereon the solar cells interconnected in the stringing station, is provided with a layer of material for covering the solar cells,
wherein at least the stringing station and the laminating station include a conveying device that is configured to convey a translucent plate through said stations.

22. An apparatus according to claim 21, wherein the tabbing station includes a conveyor configured to convey solar cell substrates.

23. An apparatus according to claim 21, wherein the tabbing station includes a tab manufacturing unit configured to manufacture tabs of a desired length from a roll of strip material.

24. An apparatus according to claim 21, wherein the tabbing station includes a punching machine configured to form lips on the tabs.

25. An apparatus according to claim 21, wherein the tabbing station includes a positioning unit configured to position tabs on a solar cell substrate.

26. An apparatus according to claim 21, wherein the tabbing station includes a device configured to connect a tab and an attachment point using a non contact connecting technique.

27. An apparatus according to claim 21, wherein the tabbing station includes soldering iron or ultrasonic welding device configured to connect a tab and an attachment point by pressing the soldering iron or ultrasonic welding device on the tab at the location of the attachment point for a short time.

28. An apparatus according to claim 26, wherein the device is mounted on a manipulator, so that the device can be quickly placed above the various attachment points of a solar cell substrate.

29. An apparatus according to claim 24, wherein the tabbing station includes a bending device configured to bend the lips at the attachment points of the solar cell substrate.

30. An apparatus according to claim 21, wherein the apparatus includes a wetting unit configured to wet a tab located in a handling unit with a liquid which promotes the establishment of a connection between the tab and the attachment point.

31. An apparatus according to claim 21, wherein the stringing station includes a conveyor configured to place solar cell substrates coming from the tabbing station, which are provided with tabs, on a translucent plate.

32. An apparatus according to claim 31, wherein the conveyor of the stringing station further comprises a conveyor of the tabbing station.

33. An apparatus according to claim 21, wherein the stringing station includes a connecting device configured to carry out a a connecting operation, said connecting device being mounted on a manipulator, so that the connecting device can be quickly place above the various attachment points of the different solar cell substrates for interconnecting the different solar cell substrates.

34. An apparatus according to claim 21, further comprising a pre-assembly station including a device configured to identify dimensions of a plate fed into the station.

35. An apparatus according to claim 21, wherein the laminating station, includes a device configured to apply a sealing layer on the interconnected solar cell substrates located on the translucent plate.

36. An apparatus according to claim 21, wherein the laminating station, includes a device configured to create connecting points for electrical connection of the solar panel.

37. A tabbing station for connecting a conductive metal strip, or tab, to a solar cell, said solar cell being provided with metallized attachment points, wherein a tab is placed at a respective attachment point, the tabbing station comprising:
a non-contact connecting technique device configured to connect a tab to an attachment point, said tab being connected to said attachment point by directing a flame at the tab at the location of the attachment point for a short time, wherein the short time is in the range of about 0.1-1.5 s.

38. A stringing station for interconnecting a number of solar cells provided with tabs, the stringing station comprising:
a non-contact connecting technique device configured to connect suitably chosen tabs of adjacent solar cells said non-contact connecting technique device comprising a flame soldering device arranged to direct a small flame formed by the flame soldering device at contact points between tabs of adjacent solar cells for a short time, wherein the short time is in the range of about 0.1-1.5 s.

39. A method according to claim 1, wherein the short time is in the range of about 0.2-0.5 s.

40. A method according to claim 5, further comprising folding the lip at the respective attachment point.

41. A method according to claim 16, wherein the non-contact connecting technique includes flame soldering, infrared soldering, laser welding or laser soldering.

42. A method according to claim 18, wherein the contact connecting technique includes flame soldering, infrared soldering, laser welding or laser soldering.

43. A method according to claim 19, wherein the contact connecting technique includes soldering with a soldering iron or welding with an ultrasonic welding device.

44. An apparatus according to claim 26, wherein the device includes a flame soldering device, an infrared soldering device, a laser welding or laser soldering device.

45. An apparatus according to claim 33, wherein the connecting operation includes flame soldering, infrared soldering, laser welding, laser soldering, ultrasonic welding or soldering using a soldering iron.

46. A tabbing station according to claim 37, wherein the short time is in the range of about 0.2-0.5 s.

47. A stinging station according to claim 37, wherein the short time is in the range of about 0.2-0.5 s.
